(19) United States
(12) Patent Application Publication
(10) Pub. No.: US 2013/0277828 A1
(43) Pub. Date: Oct. 24, 2013

(54) Methods and Apparatus for bump-on-trace Chip Packaging

(71) Applicants: Chang-Chia Huang, Hsin-Chu (TW); Tsung-Shu Lin, New Taipei (TW); Han-Ping Pu, Taichung (TW); Yen-Liang Lin, Taichung (TW); Sheng-Hsiang Chiu, Tainan (TW)

(72) Inventors: Chang-Chia Huang, Hsin-Chu (TW); Tsung-Shu Lin, New Taipei (TW); Han-Ping Pu, Taichung (TW); Yen-Liang Lin, Taichung (TW); Sheng-Hsiang Chiu, Tainan (TW)

(73) Assignee: TAIWAN SEMICONDUCTOR MANUFACTURING COMPANY, LTD., Hsin-Chu (TW)

(21) Appl. No.: 13/450,191

(22) Filed: Apr. 18, 2012

(51) Int. Cl. H01L 23/498; H01L 21/50

(52) U.S. Cl. 257/737; 438/107; 257/E21.499; 257/E23.068

(57) ABSTRACT

Methods and apparatus for a solder mask trench used in a bump-on-trace (BOT) structure to form a semiconductor package are disclosed. A solder mask layer is formed on a trace and on a substrate. An opening of the solder mask layer, called a solder mask trench, is formed to expose the trace on the substrate. The solder mask trench has a width about a size of a diameter of a solder bump. A solder bump is landed directly on the exposed trace to connect a chip to the trace by an interconnect. With the formation of the solder mask trench, the trace exposed in the solder mask trench have a better grab force, which reduces the trace peeling failure for the semiconductor package. A plurality of solder mask trench rings may be formed in a package.

### BACKGROUND

Integrated circuits or chips are made up of millions of active and passive devices such as transistors and capacitors. These devices are initially isolated from each other, and are later interconnected to form integrated circuits. Connector structures are further formed for integrated circuits, which may include bond pads or metal bumps formed on the surface of the circuits. Electrical connections are made through the bond pads or metal bumps to connect the chip to a package substrate or another die. In general, chips may be assembled into a package such as a pin grid array (PGA), or ball grid array (BGA), using wire bonding (WB) or flip chip (FC) packaging technology.

A flip-chip (FC) packaging technology may connect a chip to a package substrate using a bump-on-trace (BOT) structure, wherein the connections are made through the metal bumps to connect the chip to the metal traces of the package substrate or die. The BoT structure offers a low cost alternative to microelectronic packaging industry. However, the reliability issues for BOT structure rises as substrate structure goes thinner.

When using a BoT structure, bumps for the chip are soldered onto the trace on the package substrate by a reflow process. When the bumps are joined to the substrate and cooled down from the reflow condition to a room temperature, thermal force caused by coefficient of thermal expansion (CTE) mismatch drives the substrate shrinkage and leads to relative twist on each bump. Once stress level rises over the adhesive criteria between the substrate and the trace, a trace peeling failure occurs.

### BRIEF DESCRIPTION OF THE DRAWINGS

For a more complete understanding of the present disclosure, and the advantages thereof, reference is now made to the following descriptions taken in conjunction with the accompanying drawing, in which:

FIG. 1 illustrates an embodiment of a chip on a bump-on-trace (BOT) structure to form a flip-chip (FC) package;

FIGS. 2(a)-(c) illustrate an embodiment of a method and an apparatus of a solder mask trench used in a BOT structure to form a FC package; and

FIG. 3 illustrates a top view of a plurality of bumps connected to traces within a plurality of solder mask trench rings used in BOT structures.

The drawings, schematics and diagrams are illustrative and not intended to be limiting, but are examples of embodiments of the disclosure, are simplified for explanatory purposes, and are not drawn to scale.

### DETAILED DESCRIPTION OF ILLUSTRATIVE EMBODIMENTS

The making and using of the embodiments of the present disclosure are discussed in detail below. It should be appreciated, however, that the embodiments of the present disclosure provide many applicable concepts that can be embodied in a wide variety of specific contexts. The specific embodiments discussed are merely illustrative of specific ways to make and use the disclosure, and do not limit the scope of the disclosure.

As will be illustrated in the following, methods and apparatus for a solder mask trench used in a BOT structure to form a semiconductor package are disclosed. A solder mask layer is formed on a trace and on a substrate. An opening of the solder mask layer, called a solder mask trench, is formed to expose the trace on the substrate. A chip is connected to the trace exposed in the solder mask trench. With the formation of the solder mask trench, the trace exposed in the trench can have a better grab force, which reduces the trace peeling failure for the semiconductor package.

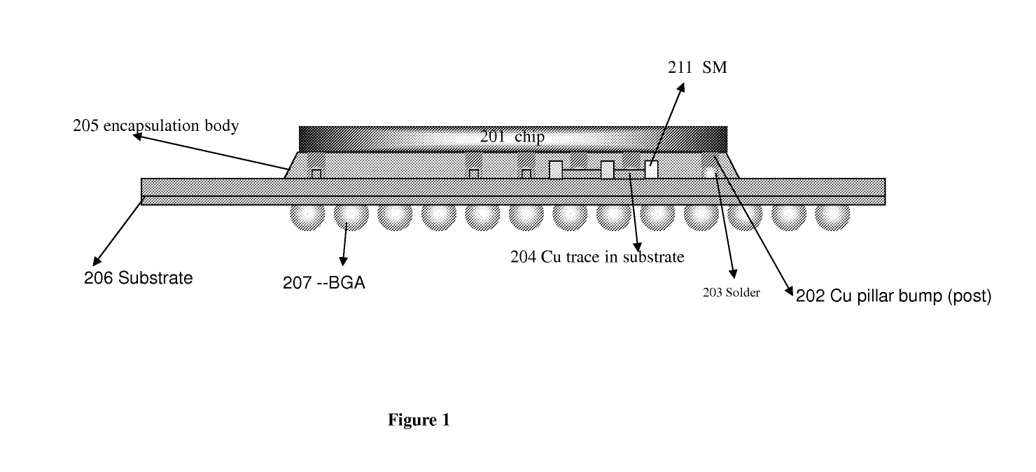

FIG. 1 is a schematic view of an illustrative embodiment of a chip 201 on a bump-on-trace (BOT) structure to form a flip-chip (FC) package. A substrate 206 may have a plurality of sub-layers. The two sub-layers of substrate 206 shown in FIG. 1 are only for illustrative purpose and are not limiting. A plurality of balls 207 under the substrate 206 may form a ball grid array (BGA). A chip 201 is connected to the substrate 206 by a plurality of interconnects wherein each interconnect comprises a Cu pillar bump or a post 202 and a solder bump 203. The solder bump 203 is placed on a trace 204 which is formed on the substrate 206. A solder mask 211 is formed on the surface of the substrate 206 covering the trace. An opening of the solder mask is formed, called a solder mask trench, which exposes the trace 204. The space between the chip 201 and the substrate 206 may be filled with a compound, forming an encapsulation body 205.

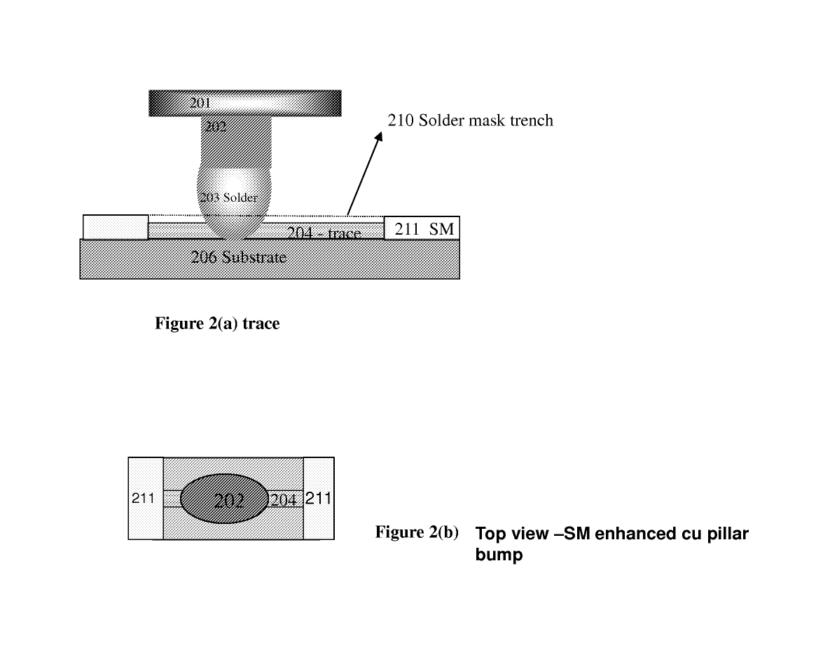

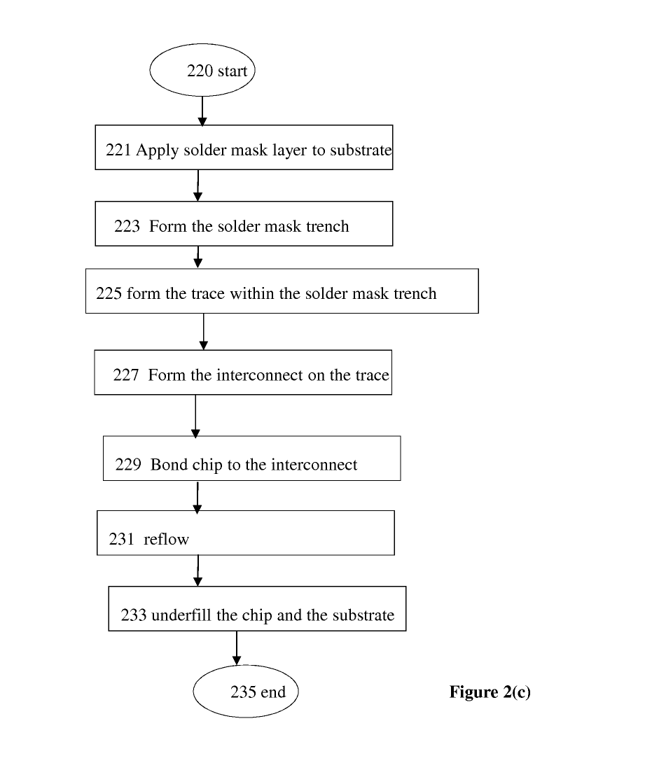

FIG. 2(a) illustrates an embodiment of a single solder mask trench 210 on a substrate 206, which may be any of the trenches in FIG. 1 where a trace is exposed and a connection to the chip 201 is made. A trace 204 is formed on the surface of the substrate 206. A solder mask layer 211 may be formed on the trace covering the trace and the surface of the substrate 206. A trench may be opened in the solder mask layer 211 to form a solder mask trench 210 to expose the trace 204. The trench has an opening big enough so that the interconnect such as the solder ball 203 may directly land on the trace contained in the opening. For example, the solder mask trench has a size about a diameter of a solder bump. The trace 204 may be connected to a chip 201 by way of an interconnect. The interconnect may comprise a solder bump 203 and a post such as a Cu pillar 202, where the solder ball 203 is placed on the trace 204 directly and surrounded by the solder mask trench. The structures shown in FIG. 2(a) are only for illustrative purpose and are not limiting. Additional embodiments can be conceived.

FIG. 2(b) illustrates the top view where a post 202 is on the trace 204, which is surrounded by the solder mask 211. The chip 201 and the substrate 206 are not shown in FIG. 2(b).

FIG. 2(c) illustrates an exemplary process of manufacturing the embodiment shown in FIG. 2(a). Details of the process shown in FIG. 2(c) are explained below.

The process starts at step 220, where a substrate such as the substrate 206 in FIG. 2(a) is provided. The substrate 206 may provide the package with the mechanical support and an interface that allows external components access to the device within the package. The substrate 206 may comprise bulk silicon, doped or undoped, or an active layer of a silicon-on-insulator (SOI) substrate. Other substrates may include multi-layered substrates, gradient substrates, or hybrid orientation substrates. The substrate 206 may further be a laminate substrate formed as a stack of multiple thin layers of a polymer material such as bismaleimide triazine, or the like.

A trace 204 may be on the surface of the substrate 206. The trace 204 may be for expanding the footprint of a die. The width or diameter of the trace may be about the same as the ball (or bump) diameter, or can be as much as two to four times narrower than the ball (or bump) diameter. For example, the trace 204 may have a line width between about 10 μm and 40 μm and trace pitch P between about 30 μm and 70 μm. The trace may have a narrow, wide, or tapered shape. The terminal of the trace may be of a different shape from the body of the trace. The trace body may be of a substantially constant thickness. The terminal of the trace and the body of the trace are formed as one piece, which is different from placing a pad on a trace. The trace may have a substantially longer length than the diameter of the ball (or bump) diameter. On the other hand, a connection pad may be of similar length or width as the ball or bump diameter.

There may be multiple traces on the substrate, each electrically insulated from one another, and the space between two adjacent traces may be between about 10 μm and 40 μm.

The trace 204 may comprise conductive materials such as Al, Cu, Au, alloys thereof, other materials, or combinations and/or multiple layers thereof, as examples. Alternatively, the trace 204 may comprise other materials. In some embodiments, a dielectric layer may cover some portions of the trace 204. The trace 204 may be covered by a metal finish, such as a layer of organic film or a mix material such as Ni/Pd/Au, coated on the trace 204.

The trace 204 and the substrate are connected by merely interfacial adhesion between them, which may not be enough grabbing force to make a strong connection between the trace 204 and the substrate 206.

At step 221, a solder mask layer such as the solder mask layer 211 shown in FIG. 2(a) may be formed on the surface of the substrate 206 covering the trace 204 and the surface of the substrate. The solder mask layer 211 may perform several functions, including providing electrical insulation resistance between the circuit traces on the substrate, chemical and corrosion resistance or protection, mechanical (scratch, wear) protection, boundaries on solder surfaces, additional grabbing force on trace, and improved dielectric reliability. The solder mask layer provides additional grabbing force between the trace 204 and the substrate 206, because the solder mask, the trace, and the substrate form a sandwich structure, where the solder mask and substrate “clib” the trace.

The solder mask layer 211 may be formed at a single step, by screening a wet film onto the substrate surface and then curing the wet film by oven baking. The thickness of the solder mask layer 211 may be about 30 to 40 microns (typically about 35 microns). The solder mask layer may comprise polymer material.

At step 223, a trench may be opened in the solder mask layer 211 to form a solder mask trench 210 to expose the trace 204, as shown in FIG. 2(a). The trench has an opening big enough so that an interconnect such as the solder ball 203 may directly land on the trace contained in the opening. A wider opening to host the solder ball can increase the connection strength between the solder ball and the trace. The size of the opening is therefore flexible and may change with the size of the solder ball used to connect to the trace. A solder mask layer 211 formed by the wet film can be screened in a pattern to form the solder mask trench 210. For example, the solder mask layer with a solder mask trench may be placed on a roller first to print on the substrate. Alternatively, a photo-sensitive material may be used to pattern the solder mask trench 210 to the cured film. The solder mask trench 210 may be formed to expose the trace 204 to further form the appropriate electrical connections with the die to be mounted on the substrate.

A solder flux (not shown) may be applied to the trace. The flux serves primarily to aid the flow of the solder, such that the solder balls 203 make good contact with traces on the substrate. It may be applied in any of a variety of methods, including brushing or spraying. The flux generally has an acidic component, which removes oxide barriers from the solder surfaces, and an adhesive quality, which helps to prevent the chip from moving on the substrate surface during the assembly process.

At step 227, a chip 201 may be connected to the trace 204 by way of an interconnect of the chip, as shown in FIG. 2(a). As illustrated in FIG. 2(a), the interconnect may comprise a solder bump 203 and a post such as a Cu pillar 202. The trench has an opening big enough so that the solder ball 203 may directly land on the trace contained in the opening.

The solder bump 203 of a chip 201 may be placed on the trace 204 exposed by the solder mask trench. The solder bump 203 may comprise a material such as tin, or other suitable materials, such as silver, lead-free tin, copper, combinations thereof, or the like. In an embodiment in which the solder bump 203 is a tin solder bump, the solder bump 203 may be formed by initially forming a layer of tin through methods such as evaporation, electroplating, printing, solder transfer, or ball placement, to a thickness of, e.g., about 15 μm, and then performing a reflow in order to shape the material into the desired bump shape. Any suitable method of producing the solder bump 203 may alternatively be utilized.

A chip such as the chip 201 shown in FIG. 2(a) may be connected to the trace 204 by the solder bump 203 and a post 202. A post 202 may be formed on the chip 201. The post 202 may be a Cu pillar or other metals with a melting temp higher than 300° C. The chip 201 may be aligned so that the post 202 is placed onto the solder bump 203. The chip may be a memory chip, or any other function chip.

The post 202 and solder bump 203 together form an interconnect of the chip. The post 202 and solder bump 203 may be formed in a plurality of shapes as appropriate to avoid nearby components, control the connection area between the chip 201 and the trace 204, or other suitable reasons. The interconnect may be in the shape of a circle, an octagon, a rectangle, an elongated hexagon with two trapezoids on opposite ends of the elongated hexagon, an oval, a diamond.

At step 231, a reflow process is performed. After the chip 201 is bond to the trace as shown in FIG. 2(a), heat may be applied to the chip 201 and the substrate 206, causing the solder balls 203 to reflow and form electrical connections between the chip 201 and the substrate 206. For one embodiment, the heat may be to a temperature of about 220 C.

At step 233, an underfill material, typically a thermo-set epoxy, may be dispensed into the gap between the chip 201 and the substrate 206. Beads of thermo-set epoxy may be applied along one edge of the chip where the epoxy is drawn under the chip by capillary action until it completely fills the gap between the chip and the substrate. It is important that the underfill material is uniformly dispersed in the gap.

A separate bead of epoxy may also be dispensed and bonded around the perimeter of the chip 201. Afterwards, both the underfill and perimeter bonding epoxy are cured by heating the substrate and chip to an appropriate curing temperature, which form an encapsulation body such as the encapsulation body 205 shown in FIG. 1. The encapsulation body 205 has filled the gap between the chip 201 and the substrate 206. In this manner the process produces a mechanically, as well as electrically, bonded semiconductor chip assembly, when the process ends.

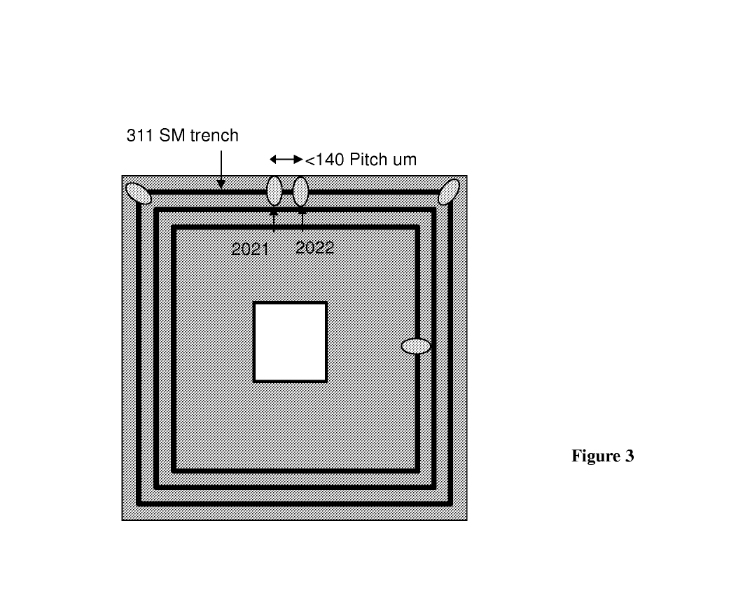

FIG. 3 illustrates a top view of the substrate of a semiconductor package formed by BOT structures. The surface of the substrate may be covered by solder mask, except the area 301. The solder mask may cover the surface of the substrate in other shapes as well. There may be a plurality of solder mask trench 311 formed on the solder mask layer. The solder mask trenches surround the center area of the substrate, and form a plurality of solder mask trench rings. The shape of the solder mask trench follows the contour of the trace on the substrate. There may be other shapes instead of solder mask rings formed. There are three such solder mask trench rings formed in FIG. 3. There may be other number of solder mask trench rings formed. A plurality of posts or interconnects such as 2021 and 2022 may be placed on traces exposed within the solder mask trenches. The pitch between two posts or two interconnects may be less than about 140 um.

Although the present disclosure and its advantages have been described in detail, it should be understood that various changes, substitutions and alterations can be made herein without departing from the spirit and scope of the disclosure as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps. In addition, each claim constitutes a separate embodiment, and the combination of various claims and embodiments are within the scope of the disclosure.

1. A device comprising:
a substrate;
a trace on the substrate,
a solder mask layer on the substrate and on the trace, wherein the solder mask layer has a solder mask trench to expose the trace, and the solder mask trench has a width about a size of a diameter of a solder bump; and
a solder bump landed directly on the trace exposed by the solder mask trench wherein the solder bump is a part of an interconnect of a chip.

2. The device of claim 1, further comprising a chip connected to the interconnect.

3. The device of claim 2, further comprising an under-fill material filling a gap between the chip and the substrate.

4. The device of claim 1, wherein the substrate is made of a laminate or an organic material.

5. The device of claim 1, wherein the solder mask layer is about 30 to 40 microns in height.

6. The device of claim 1, wherein the trace comprises a material selected from a group consisting essentially of pure copper, aluminum copper, or alloys.

7. The device of claim 1, wherein the trace has a trace body that is of a substantially constant thickness.

8. The device of claim 1, wherein the interconnect is of a shape of a circle, an octagon, a rectangle, an oval, or a diamond.

9. The device of claim 1, wherein the interconnect comprises a post and the solder bump.

10. The device of claim 1, wherein the solder bump comprises a material selected from a group consisting essentially of tin, silver, lead-free tin, copper, or a combination thereof.

11.-17. (canceled)

18. A semiconductor package, comprising:
a substrate with a plurality of traces;
a solder mask layer on the substrate and the plurality of traces;
a trench in the solder mask layer to expose portions of the plurality of traces; and
at least one solder bump landed directly on at least one of the exposed plurality of traces, wherein the solder bump is a part of an interconnect of a chip.

19. The package of claim 18, wherein a pitch between two interconnects is less than about 140 um.

20. The device of claim 1, wherein the trace has a trace body that is of a substantially constant thickness.

21. A device comprising:
a trace on a substrate,
a solder mask layer on the trace, wherein the solder mask layer has a solder mask trench to expose the trace, and the solder mask trench has a width about a size of a diameter of a connector; and
the connector landed on the trace exposed by the solder mask trench wherein the connector is a part of an interconnect of a chip.

22. The device of claim 21, further comprising a chip connected to the interconnect.

23. The device of claim 21, wherein the solder mask layer is about 30 to 40 microns in height.

24. The device of claim 21, wherein the trace comprises a material selected from a group consisting essentially of pure copper, aluminum copper, or alloys.

25. The device of claim 21, wherein the trace has a trace body that is of a substantially constant thickness.

26. The device of claim 21, wherein the interconnect is of a shape of a circle, an octagon, a rectangle, an oval, or a diamond.

27. The device of claim 21, wherein the interconnect comprises a post and a solder bump.
